(19) United States
(12) Patent Application Publication
(10) Pub. No.: US 2015/0181749 A1
(43) Pub. Date: Jun. 25, 2015

(54) SERVER CASING

(71) Applicants: Fu Tai Hua Industry (Shenzhen) Co., Ltd., Shenzhen (CN); HON HAI PRECISION INDUSTRY CO., LTD., New Taipei (TW)

(72) Inventor: HAI-TAO GONG, Shenzhen (CN)

(73) Assignees: HON HAI PRECISION INDUSTRY CO., LTD., New Taipei (TW); FU TAI HUA INDUSTRY (SHENZHEN) CO., LTD., Shenzhen (CN)

(21) Appl. No.: 14/264,702

(22) Filed: Apr. 29, 2014

(30) Foreign Application Priority Data
Dec. 23, 2013 (CN) 2013107159743

(51) Int. Cl. H05K 7/14; H05K 5/02

(52) U.S. Cl. CPC H05K 7/1488; H05K 5/0239; H05K 5/0221

(57) ABSTRACT

A server casing includes a main body, a front panel, a rotatable assembly, and a locking assembly. A retaining member is coupled to a bottom surface of the main body and defines an aperture. A hook protrudes from a top surface of the front panel. A rotatable assembly is movably coupled to the retaining member and includes a sliding block and an arm. The sliding block is slidably received in the aperture. The arm is coupled to the sliding block and the top surface. The front panel can rotate about the main body via the rotatable assembly, to allow the server casing to be in an open position and a closed position. The locking assembly is secured to the bottom surface. The locking assembly is engaged with the hook when the casing is in the closed position, and disengaged from the hook when the front panel is pressed.

### FIELD

The present disclosure relates to server casings, and particularly to a server casing including a main body and a front panel rotatably coupled to the main body.

### BACKGROUND

Server casings usually include a main body and a front panel. Typically, a latching assembly is applied to lock the front panel to the main body. The latching assembly may push the front panel away from the main body when unlocking the server casing.

### BRIEF DESCRIPTION OF THE DRAWINGS

Many aspects of the embodiments with this disclosure can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the views. The description is not to be considered as limiting the embodiments described herein.

FIG. 1 is an isometric view of an embodiment of a server casing in a closed position, the server casing including a main body and a front panel.

FIG. 2 is similar to FIG. 1, but showing the front panel disengaged from the main body.

FIG. 3 is an isometric view of an embodiment of the server casing of FIG. 1 in an open position.

FIG. 4 is an exploded view of the server casing of FIG. 3.

FIG. 5 is a cross-sectional view taken along line V-V of FIG. 1.

FIG. 6 is a cross-sectional view taken along line VI-VI of FIG. 1.

FIG. 7 is an enlarged view of a circled portion VII in FIG. 6.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, such references mean “at least one.”

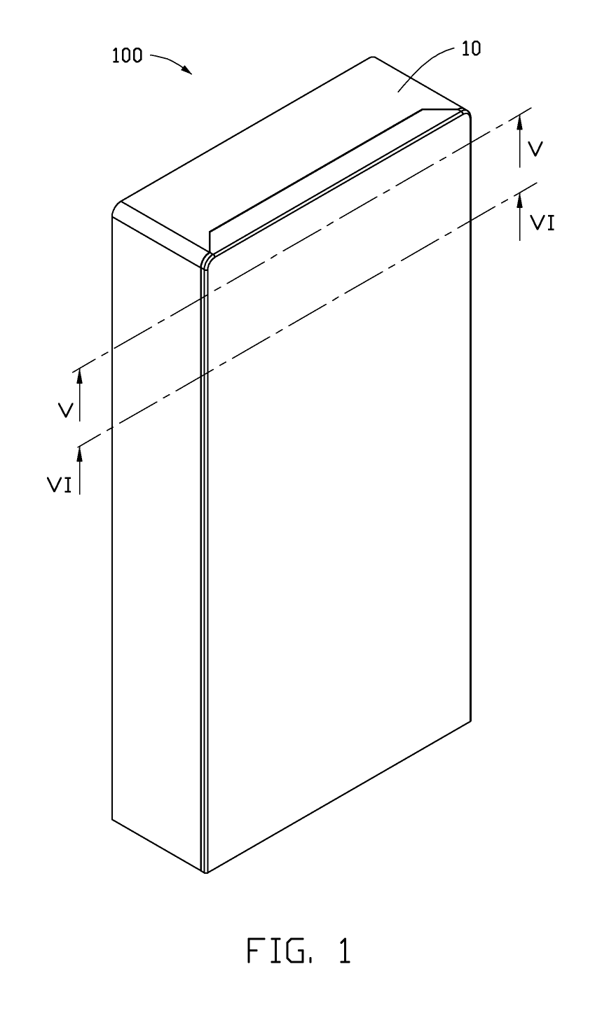

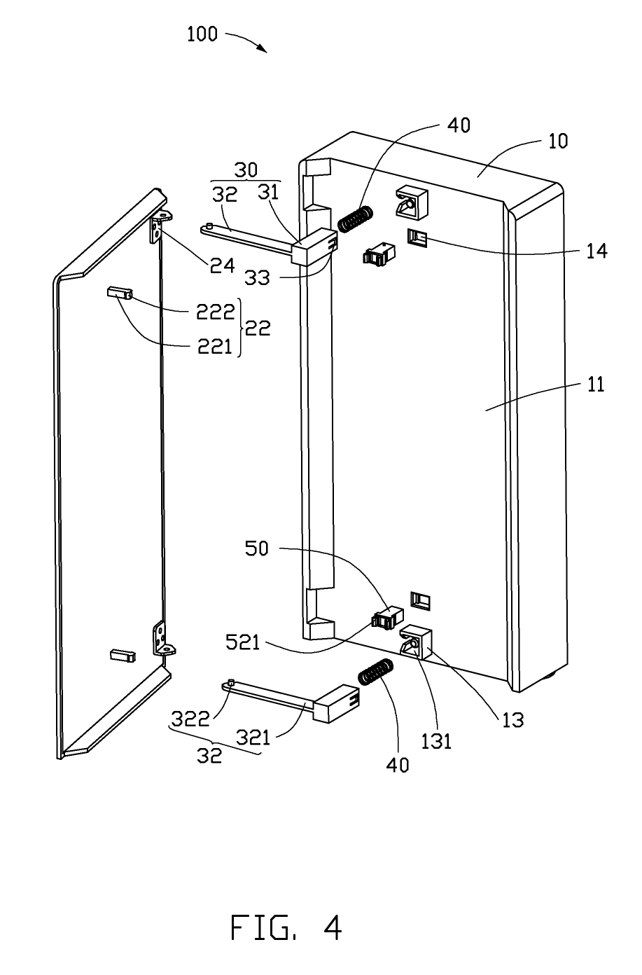

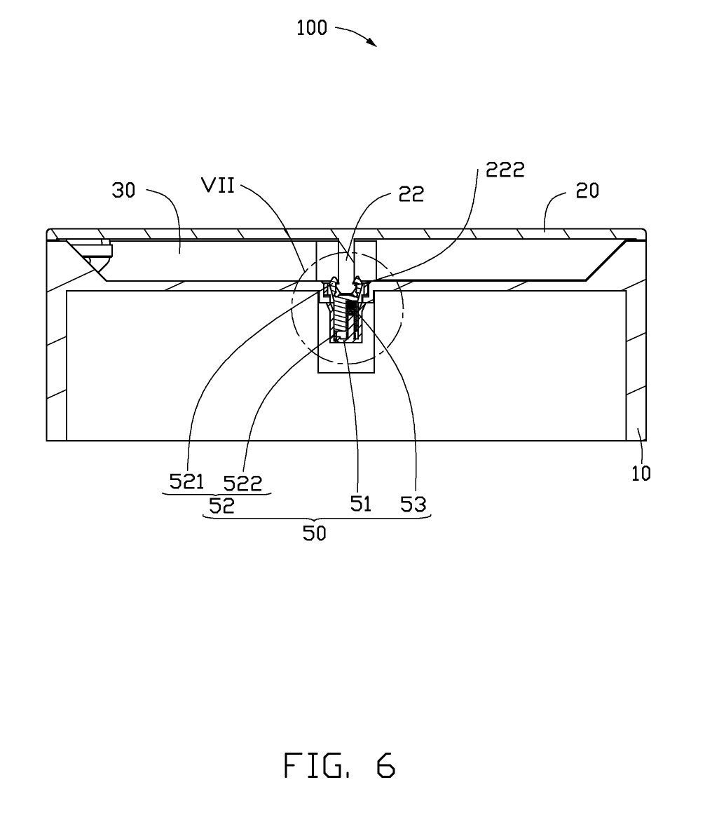

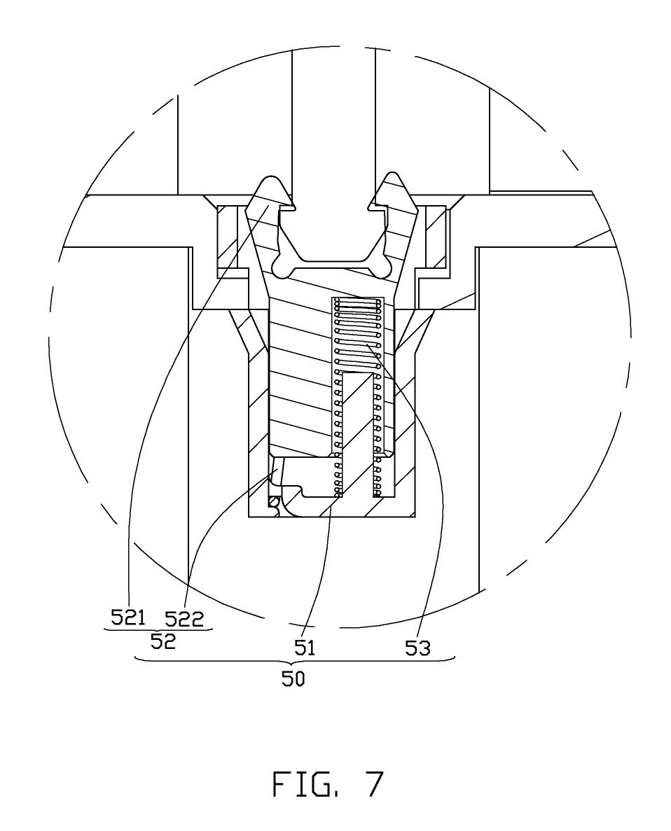

FIGS. 1-7 illustrate an embodiment of a server casing 100. The server casing 100 includes a main body 10, a front panel 20, two rotatable assemblies 30, two first elastic members 40, and two locking assemblies 50. The front panel 20 can rotate about the main body 10 via the rotatable assembly 30. It is notable that numbers of the first elastic member 40 and the locking assembly 50 are not limited.

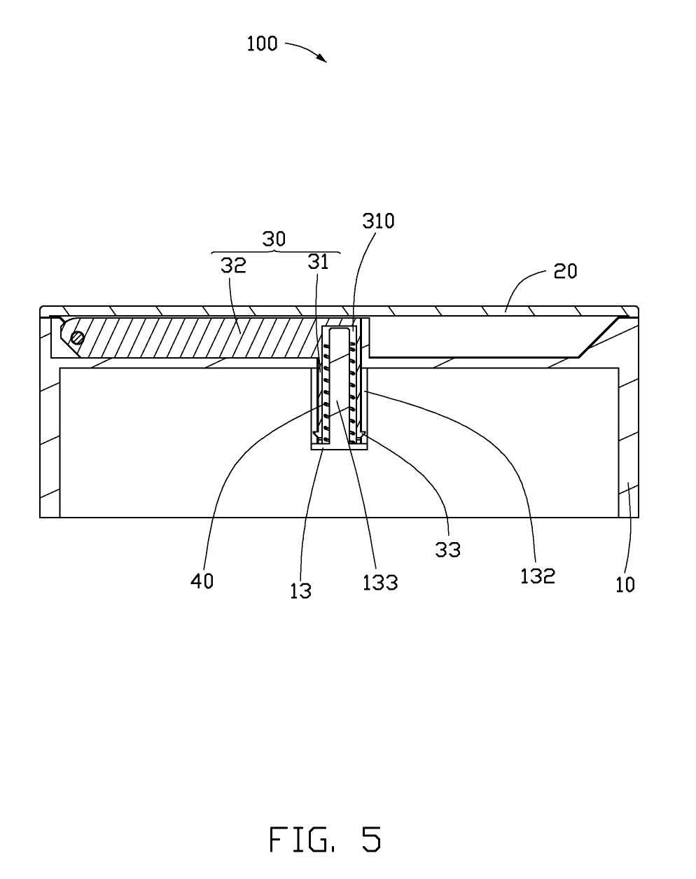

The main body 10 includes a bottom surface 11, two retaining members 13 secured to the bottom surface 11, and two fixing holes 14 defined in the bottom surface 11. Each retaining member 13 can be substantially rectangular and define an aperture 131 in a substantially central portion thereof. Two latching slots 132 (shown in FIG. 5) are defined in opposite interior sides of the retaining member 13.

The front panel 20 includes a top surface 21 facing the bottom surface 11, two hooks 22 protruding from the top surface 21, and two connecting members 24 coupled to the top surface 21. In at least one embodiment, the connecting member 24 can be integrally formed with the front panel 20. The hook 22 includes a leg 221 coupled to the top surface 21, and a hook portion 222 coupled to the leg 221.

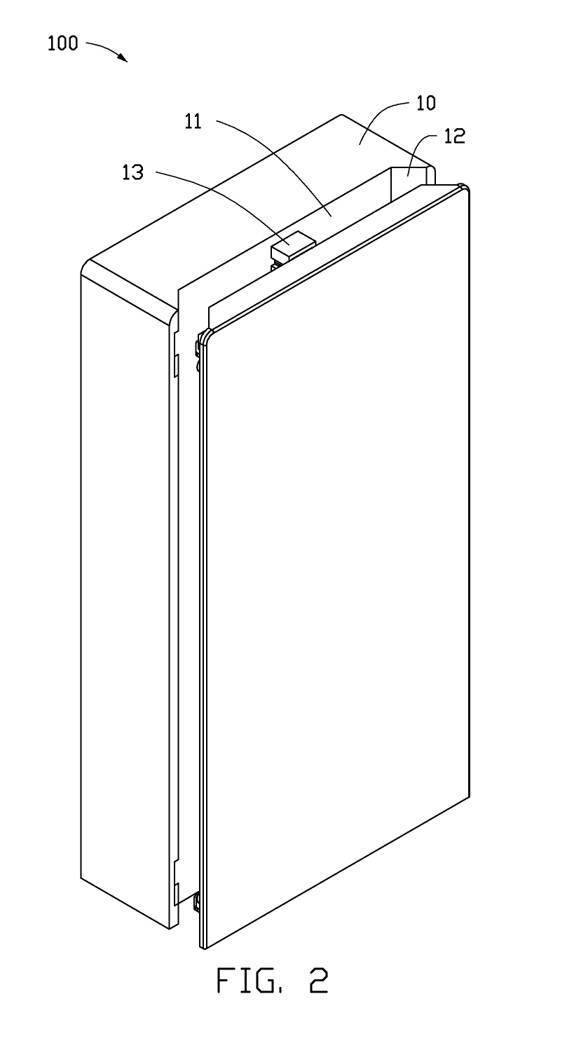

Each rotatable assembly 30 is movably coupled to the corresponding retaining member 13. The rotatable assembly 30 includes a sliding block 31, an arm 32, and two elastic hooks 33. A first end portion 321 of the arm 32 is coupled to one end portion of the sliding block 31, and a second end portion 322 of the arm 32 is coupled to the connecting member 24. The elastic hooks 33 are coupled to opposite exterior sides of the sliding block 31. The sliding block 31 can be inserted into the aperture 131 when a user presses the front panel 20. The elastic hooks 33 can snap into the latching slots 132 when the sliding block 31 is inserted into the aperture 131, thereby preventing the sliding block 31 from disengaging from the retaining member 13. Thus, as shown in FIGS. 1-2, when the front panel 20 is rotated about the main body 10 via the rotatable assemblies 30 until the top surface 21 is substantially parallel to the bottom surface 11, the server casing 100 is locked in a closed position.

Each first elastic member 40 is received in the corresponding aperture 131, and is compressed when the corresponding sliding block 31 is inserted into the aperture 131. The first elastic member 40 is capable of pushing the sliding block 31 away from the sliding slot 131 when released. In the illustrated embodiment, a positioning post 133 is arranged in the aperture 131. The sliding block 31 defines a positioning hole 310 corresponding to the first elastic member 40. The first elastic member 40 is a coil spring received in the positioning hole 310 and sleeved around the positioning post 133.

Each locking assembly 50 is secured in the corresponding fixing hole 14. The locking assembly 50 includes a hollow housing 51, a latching portion 52, and a second elastic member 53. The latching portion 52 is slidably received in the housing 51. A first end portion of the latching portion 52 includes two first elastic latches 521, and a second end portion of the latching portion 52 includes a second elastic latch 522. The first elastic latches 521 protrude outwardly from the fixing hole 14. When the user presses the front panel 20, the latching portion 52 is pushed by the hook 22, and the first elastic latches 521 are compressed by the housing 51 to grab the hook portion 222. Then, the second elastic latch 522 engages with the housing 51. The second elastic member 53 is arranged between the latching portion 52 and the housing 51, and compressed when the latching portion 52 is pushed by the hook 22.

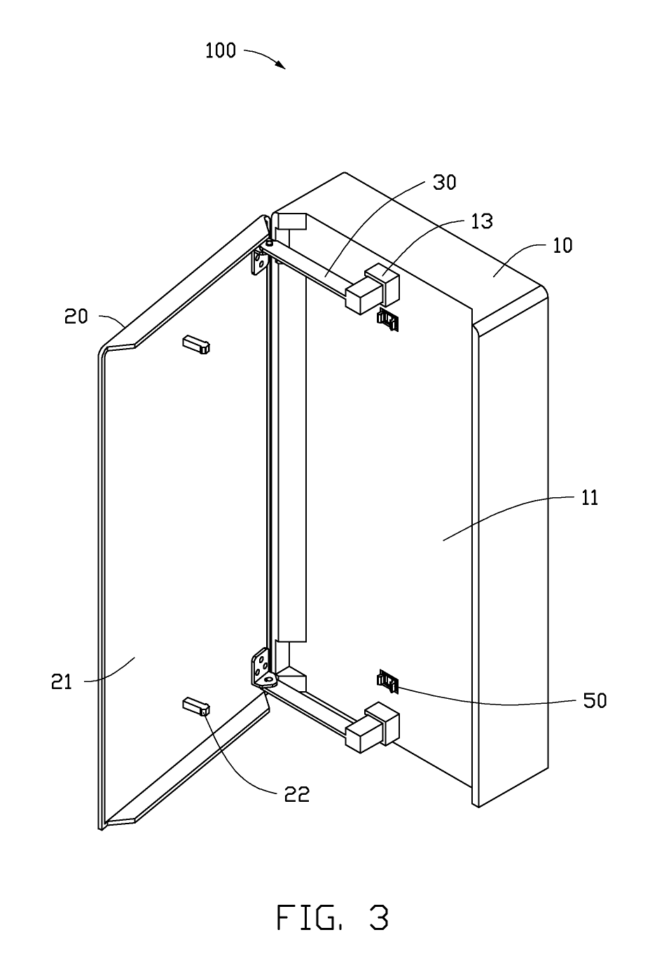

To unlock the server casing 100, the user can further press the front panel 20. Then, the latching portion 52 is pushed by the hook 22 again, causing the second elastic latch 522 to disengage from the housing 51. The second elastic member 53 pushes the latching portion 52 away from the housing 51 when released, and the first elastic latches 521 disengage from the hook portion 222 when protruding outwardly from the fixing hole 14. The first elastic member 40 rebounds to push the sliding block 31 away from the aperture 131, and the sliding block 31 pushes the front panel 20 to rotate about the main body 10. Thus, as shown in FIG. 3, the server casing 100 is in an open position.

It is to be understood, even though information and advantages of the present embodiments have been set forth in the foregoing description, together with details of the structures and functions of the present embodiments, the disclosure is illustrative only; and that changes may be made in detail, especially in matters of shape, size, and arrangement of parts within the principles of the present embodiments to the full extent indicated by the plain meaning of the terms in which the appended claims are expressed.

What is claimed is:

1. A server casing, comprising:
a main body comprising a bottom surface;
a retaining member coupled to the bottom surface, the retaining member defining an aperture;
a front panel comprising a top surface;
at least one hook protruding from the top surface;
a rotatable assembly movably coupled to the retaining member, and comprising a sliding block and an arm, the sliding block slidably moved in the aperture, the arm coupled to the sliding block at a first end portion and coupled to the top surface at a second end portion, the front panel able to be rotated about the main body via the rotatable assembly to allow the server casing to be in an open position and a closed position; and
at least one locking assembly secured to the bottom surface, the locking assembly engaged with the hook when the casing is in the closed position, and disengaged from the hook when the front panel is pressed.

2. The server casing of claim 1, wherein the front panel further comprises at least one connecting member coupled to the top surface, and the second end portion of the arm is coupled to the connecting member.

3. The server casing of claim 2, wherein the connecting member is integrally formed with the front panel.

4. The server casing of claim 1, wherein at least two latching slots are defined in opposite interior sides of the retaining member, the rotatable assembly further comprises at least two elastic hooks coupled to opposite exterior sides of the sliding block, each elastic hook snaps into the corresponding latching slot when the sliding block is inserted into the aperture, thereby preventing the sliding block from disengaging from the retaining member.

5. The server casing of claim 4, wherein a first elastic member is received in the aperture, and is compressed when the sliding block is inserted into the aperture, and the first elastic member pushes the sliding block away from the sliding slot when released.

6. The server casing of claim 5, wherein a positioning post is arranged in the aperture, the sliding block defines a positioning hole, the first elastic member is a coil spring received in the positioning hole and sleeved around the positioning post.

7. The server casing of claim 1, wherein at least one fixing hole is defined in the bottom surface, the locking assembly is secured to the corresponding fixing hole, the locking assembly comprises a hollow housing and a latching portion, the latching portion is slidably received in the housing, the latching portion comprises at least two first elastic latches and a second elastic latch, the first elastic latches protrude outwardly from the fixing hole, and are compressed by the housing to grab the hook when the latching portion is pushed by the hook, the second elastic latch then engages with the housing.

8. The server casing of claim 7, wherein the locking assembly further comprises a second elastic member arranged between the latching portion and the housing, the second elastic member is compressed when the latching portion is pushed by the hook, when the latching portion is pushed by the hook again, and the second elastic latch disengages from the housing, the second elastic member pushes the latching portion away from the housing when released, and the first elastic latches disengage from the hook when protruding outwardly from the fixing hole.
